(19) United States
(12) Patent Application Publication
(10) Pub. No.: US 2017/0265300 A1
(43) Pub. Date: Sep. 14, 2017

(54) DOUBLE-SIDED PRINTED CIRCUIT BOARD AND METHOD FOR MANUFACTURING SAME

(71) Applicant: SHUNSIN TECHNOLOGY (ZHONG SHAN) LIMITED, Zhongshan (CN)

(72) Inventors: HONG-GUANG HUANG, Shenzhen (CN); SHUN-LONG LEE, New Taipei (TW)

(21) Appl. No.: 15/166,222

(22) Filed: May 26, 2016

(30) Foreign Application Priority Data
Mar. 8, 2016 (CN) 201610129795.5

(51) Int. Cl. H05K 1/11; H05K 1/09; H05K 3/00; H05K 3/06; H05K 3/12; H05K 3/16; H05K 3/02; H05K 3/18; H05K 1/03; H05K 3/40

(52) U.S. Cl. CPC H05K 1/115; H05K 1/0306; H05K 1/092; H05K 3/0011; H05K 3/4061; H05K 3/1225; H05K 3/16; H05K 3/027; H05K 3/188; H05K 3/06; H05K 2201/10545

(57) ABSTRACT

A double-sided printed circuit board and method for manufacturing requires a ceramic substrate, two circuit layers, and conductive paste. The ceramic substrate includes two opposite surfaces, and at least one through hole passing through the two opposite surfaces. The two circuit layers can be plated on the two opposite surfaces. The conductive paste is infilled into the full extent of the through hole and thermo-cured, the ingress of electroplating materials into the hole is thus prevented. The method has low process requirement and high reliability in use.

### FIELD

The disclosure generally relates to printed circuit boards, and particularly to double-sided printed circuit board and methods for manufacturing such double-sided printed circuit board.

### BACKGROUND

Miniaturization is a constant goal, thereby leading to the application of double-sided printed circuit boards to achieve higher density and performance.

A typical method for manufacturing the double-sided printed circuit board includes the following steps. Firstly, a ceramic substrate with through holes in preset positions is provided. Secondly, a metal layer is plated on an inner surface of each of the through holes to make the through holes be conductive. Thirdly, two circuit layers are disposed on two opposite surfaces of the ceramic substrate with liquid metal. However, liquid metal is difficult to deposit on the inner surfaces of the through holes because of the through holes are mostly perpendicular to the surfaces of the ceramic substrate.

A double-sided printed circuit board can also be manufactured by setting bonding pads on two opposite sides of each of the through holes and filling the through holes with conductive materials. However, the conductive materials are molten, thus oxidation of the components on the ceramic substrate is likely.

Different methods of manufacturing double-sided printed circuit board would be beneficial.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout several views.

FIG. 1 is a schematic view of a double-sided printed circuit board according to an embodiment of the disclosure.

FIG. 2 schematically illustrates a flow chart of a method of manufacturing the double-sided printed circuit board according to an embodiment of the disclosure.

FIGS. 3-9 show the sectional structure of a double-sided printed circuit board, according to the method of FIG. 2, advancing in incremental steps.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The term “comprising,” when utilized, means “including, but not necessarily limited to”; it specifically indicates open-ended inclusion or membership in the so-described combination, group, series and the like.

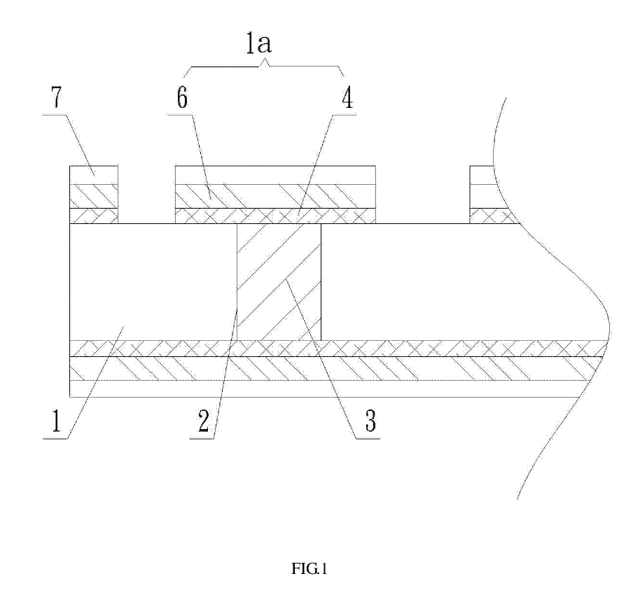

FIG. 1 shows a double-sided printed circuit board in an embodiment of the disclosure. The double-sided printed circuit board comprises a ceramic substrate 1 used as a supporting base. The ceramic substrate 1 includes two opposite surfaces and at least one through hole 2 passing through the two opposite surfaces. The position of the through hole 2 can be predetermined according to the desired circuit layout design of the double-sided printed circuit board. The ceramic substrate 1 is preferably made of alumina ceramic, aluminum nitride ceramic, or beryllium nitride ceramic to meet the needs for insulation and heat dissipation of the high-integration double-sided printed circuit board.

In the embodiment of the disclosure, each of the two opposite surfaces has a circuit layer 1a plated thereon, the circuit layer 1a is used with fixing devices to solder or otherwise fix external electronic components thereto. In general practice, circuits are formed on ceramic substrate by means of electroplating. However, the ceramic substrate 1 is an insulator, thus in an embodiment, the circuit layer 1a comprises a first metallic layer 4 sputtered on each of the two opposite surfaces and a second metallic layer 6 electroplated on the first metallic layer 4. In the process of electroplating, the first metallic layer 4 can be sputtered on each of the two opposite surfaces at first, the first metallic layer 4 can be used as a seed layer, and then the second metallic layer 6 can be electroplated on the first metallic layer 4. The circuit layer 1a is formed by the first metallic layer 4 and the second metallic layer 6 together.

Conductive thick-film paste 3 is infilled in the through hole 2 and fired to form a conductive column, one end of the conductive column connects to one circuit layer to achieve electrical connection between the two circuit layers 1a. The conductive paste 3 may optimally be conductive ink. By thermo-curing, the conductive ink can be formed into compact conductive column tightly joined with the inner surface of the through hole 2, providing high reliability.

In an illustrated embodiment, the double-sided printed circuit board further comprises a protective film 7 formed on the circuit layers 1a. The protective film 7 may be made of Ni, or Au, or an alloy of Ni and Au.

The double-sided printed circuit board of the disclosure has improvements in at least the following aspects:

1) Processing sequence can be adjusted to reduce the process requirements. The conductive paste being infilled and thermo-cured in the through hole 2 before the electroplating of the circuit layer 1a, the liquid metal for electroplating is thus prevented from entering the through hole 2 by the presence of the conductive column.

2) Ceramic substrate 1 has reliable insulation performance and good capability of heat dissipation.

3) The conductive ink can be formed into a compact conductive column and tightly joined with the inner surface of the through hole 2, contributing to high reliability during use.

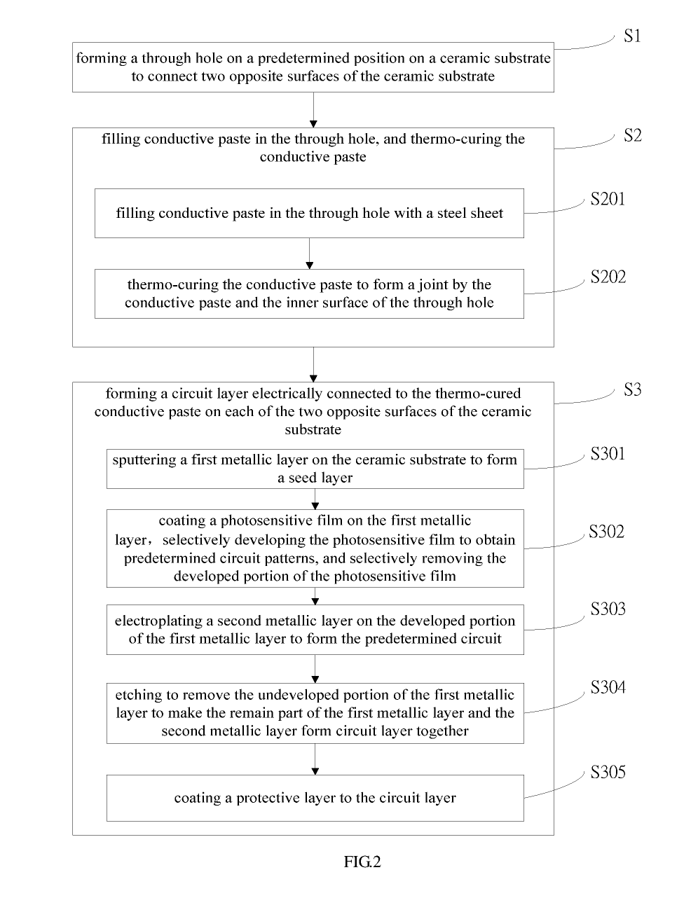

As shown in FIG. 2, the method for manufacturing double-sided printed circuit board comprises the following steps.

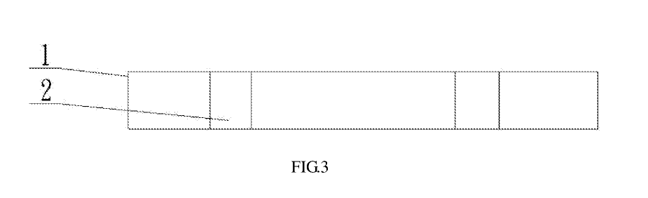

In step S1, referring to FIG. 3, a through hole 2 is formed in a predetermined position on a ceramic substrate 1 to connect two opposite surfaces of the ceramic substrate 1.

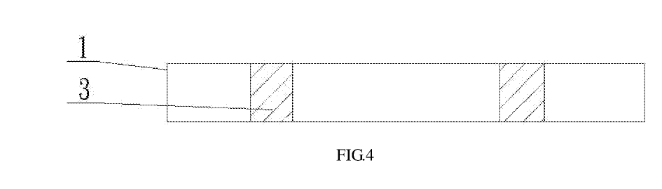

In step S2, referring to FIG. 4, conductive paste 3 is infilled in the through hole 2 and thermo-cured.

In an exemplary embodiment of the disclosure, the step S2 may specifically comprise steps S201 and S202 as follows.

In step S201, the conductive paste 3 is infilled in the through hole 2 with a stencil.

In step S202, the conductive paste 3 is thermo-cured to form a joint along and within the inner surface of the through hole.

In step S3, a circuit layer 1a is formed on each of the two opposite surfaces of the ceramic substrate 1, each circuit layer 1a is electrically connected to the fired conductive thick-film paste 3.

In another exemplary embodiment of the disclosure, the step S3 may specifically comprise steps S301 to S305 as follows.

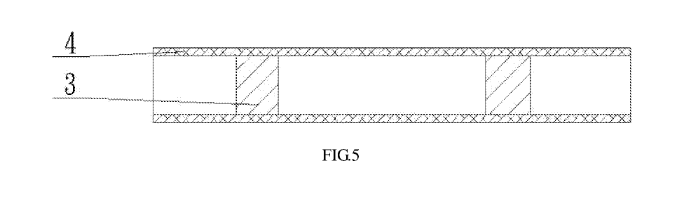

In step S301, referring to FIG. 5, a first metallic layer 4 is sputtered on the ceramic substrate 1 to form a seed layer. Since the ceramic substrate 1 is not electrically conductive, a seed layer being formed at first to meet the needs of electroplating procedure afterwards is necessary.

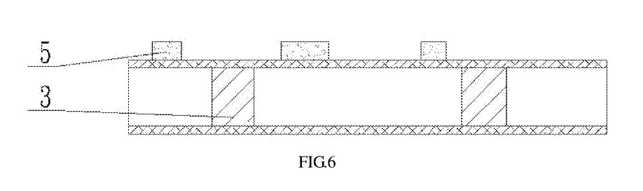

In step S302, referring to FIG. 6, a photosensitive film is coated on the first metallic layer 4, and then the photosensitive film is selectively developed to obtain predetermined circuit patterns. The developed portion of the photosensitive film is selectively removed to expose the portion of circuit patterns on the first metallic layer 4.

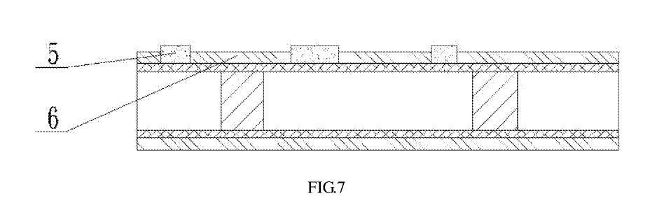

In step S303, referring to FIG. 7, a second metallic layer 5 is electroplated on the exposed portion of the first metallic layer 4 to form the predetermined circuit.

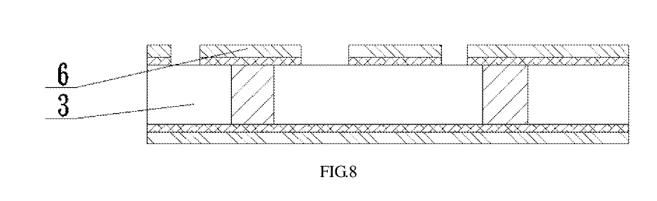

In step S304, referring to FIG. 8, the unexposed portion of the first metallic layer 4 is removed by etching to make the remaining part of the first metallic layer 4 and the second metallic layer 5 form the circuit layer 1a together.

An exemplary embodiment of the disclosure further comprises step S305 after step S304, as follows.

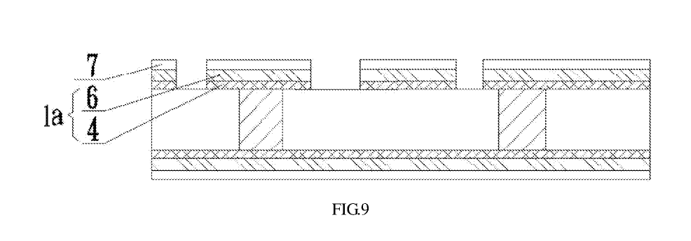

In step S305, referring to FIG. 9, a protective layer 7 is coated onto the circuit layer 1a, the protective layer 7 may be made of Ni or Au or an alloy of Ni and Au.

The through hole 2 is fully infilled with the conductive paste 3, preventing the liquid metal for electroplating from entering the through hole 2, thereby avoiding pollution to the procedure afterwards or malfunction of the circuit layer 1a. Furthermore, the procedure of infilling the conductive paste 3 can be directly observed and controlled, ensure reliable creation of the electrical connection between the two circuit layers 1a.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

1. A double-sided printed circuit board, comprising:
a ceramic substrate including two opposite surfaces, and at least one through hole passing through the two opposite surfaces;
two circuit layers plated on the two opposite surfaces; and
a conductive thick-film paste filled and fired in the at least one through hole to electrically connect the two circuit layers.

2. The double-sided printed circuit board of claim 1, wherein the circuit layer comprises a first metallic layer sputtered on each of the two opposite surfaces, and a second metallic layer electroplated on the first metallic layer.

3. The double-sided printed circuit board of claim 1, wherein the conductive thick-film paste is conductive ink.

4. The double-sided printed circuit board of any one of claim 1, wherein two protective films are formed on the corresponding circuit layers.

5. The double-sided printed circuit board of claim 4, wherein the protective film is made of Ni, or Au, or an alloy of Ni and Au.

6. (canceled)

7. (canceled)

8. (canceled)

9. (canceled)
